(19) United States
(12) Patent Application Publication
(10) Pub. No.: US 2020/0368712 A1
(43) Pub. Date: Nov. 26, 2020

(54) PRODUCTION APPARATUS FOR CARBON NANOHORN AGGREGATE

(71) Applicant: NEC CORPORATION, Tokyo (JP)

(72) Inventor: Ryota YUGE, Tokyo (JP)

(73) Assignee: NEC CORPORATION, Tokyo (JP)

(21) Appl. No.: 16/636,214

(22) PCT Filed: Aug. 4, 2017
(86) PCT No.: PCT/JP2017/028377

§ 371 Date: Feb. 3, 2020

(51) Int. Cl. B01J 19/12; C01B 32/18; C23C 14/28; C23C 14/06

(52) U.S. Cl. CPC B01J 19/121; C01B 32/18; C23C 14/28; C23C 14/0605; C01P 2004/03; B01J 2219/12; B01J 2219/0879; B01J 2219/0869; C01P 2004/04; C01P 2004/50

(57) ABSTRACT

A production apparatus for manufacturing carbon nanohorn aggregates including fibrous carbon nanohorn aggregates includes a target holding unit holding a cylindrical carbon target containing Fe or another metal catalyst, a light source irradiating a laser beam on the surface of the carbon target, a production chamber configured to irradiate the carbon target with the laser beam in a non-oxidizing gas atmosphere to produce a product including the CNB, a collection mechanism collecting the product, a rotation mechanism rotating the carbon target, and a moving mechanism moving the carbon target in the axial direction thereof.

### TECHNICAL FIELD

The present invention relates to an apparatus for producing carbon nanohorn aggregates including fibrous carbon nanohorn aggregates.

### BACKGROUND ART

Conventionally, carbon materials are utilized as conductive materials, catalyst carriers, adsorbents, isolators, inks, toners, etc., and in recent years, the appearance of nanocarbon materials having nano-size such as carbon nanotubes, carbon nanohorn aggregates, etc. have attracted attention as features as their structures.

The present inventor has found, unlike conventional globular carbon nanohorn aggregates (referred to as CNHs), a fibrous carbon nanohorn aggregates (carbon nanobrush: referred to as CNB) composed of radially assembled carbon nanohorns and having a fiber-like elongated structure (Patent Document 1). CNB is produced by laser ablation, while rotating the carbon target containing a catalyst (Patent Document 1).

Further, an apparatus for producing a conventional CNHs is disclosed in Patent Document 2. The apparatus of Patent Document 2 includes a production chamber configured to irradiate a solid carbon material with a laser beam in an atmosphere of inert gas to produce a product including carbon nanohorns, a graphite component and an amorphous component, and a separation mechanism configured to separate the carbon nanohorns from the graphite component and the amorphous component. Further, it is described that the carbon nanohorn is obtained as an aggregate having diameters of about 50-150 nm (the CNHs herein).

### PRIOR-ART LITERATURE

### Patent Document

Patent Document 1: WO2016/147909 Publication
Patent Document 2: Japanese Patent No. 5169824

### SUMMARY OF INVENTION

### Technical Problems

CNB is obtained by laser irradiation of a carbon target containing a catalyst, and both CNB and CNHs are produced. At this time, the proportion of CNB in the product is very small, and the method to produce CNB industrially has not been established.

In the present invention, an object thereof is to provide an apparatus for industrially producing CNB.

### Solution to Problem

Accordingly, an aspect of the present invention provides production apparatus for manufacturing carbon nanohorn aggregates including fibrous carbon nanohorn aggregates, the apparatus includes:

a target holding unit holding a cylindrical carbon target containing a metal catalyst selected from a single body of Fe, Ni, Co or a mixture of these two or three,

a light source irradiating a laser beam on the surface of the carbon target,

a production chamber configured to irradiate the carbon target with the laser beam in an atmosphere of non-oxidizing gas to produce a product including a fibrous carbon nanohorn aggregate,

a collection mechanism collecting the product,

a rotation mechanism rotating the carbon target, and

a moving mechanism moving the carbon target in the axial direction, wherein the apparatus further includes a control unit being provided for controlling the rotation mechanism and the moving mechanism so that the power density of the laser beam irradiated to the surface of the carbon target is substantially constant, and the irradiation position of the laser beam is moved to a region adjacent to a region previously irradiated by the laser beam, an interval being formed therebetween that is equal to or larger than the width of an altered region formed on the periphery of the region irradiated by the laser beam.

### Effects of Invention

According to one aspect of the present invention, there can be provided an apparatus capable of industrial production of fibrous carbon nanohorn aggregates (CNBs).

### BRIEF DESCRIPTION OF DRAWINGS

FIG. 1 is a schematic diagram of an apparatus for producing the carbon nanohorn aggregates according to an example embodiment of the present invention;

FIG. 2 is a schematic diagram of an apparatus for producing the carbon nanohorn aggregates according to an example embodiment of the present invention;

FIG. 3 is a diagram illustrating an irradiation position of the carbon target and a modified region by laser irradiation according to an example embodiment of the present invention;

FIG. 4 is a transmission electron microscopic image of the carbon nanohorn aggregates produced by an example embodiment;

FIG. 5 is a scanning electron microscopic image of the carbon nanohorn aggregates produced by an example embodiment;

FIG. 6 is a transmission electron microscopic image of the fibrous carbon nanohorn aggregates produced by an example embodiment;

FIG. 7 is a scanning electron microscopic image of the carbon nanohorn aggregates produced by an example embodiment;

FIG. 8 shows particle-size distributions by dynamic light-scattering measurements of CNBs and CNHs produced by Experimental Example 1; and

FIG. 9 is a scanning electron microscopic image of the carbon nanohorn aggregates produced by Comparative Experimental Example.

### DESCRIPTION OF EMBODIMENT

Hereinafter, example embodiments of the present invention will be described.

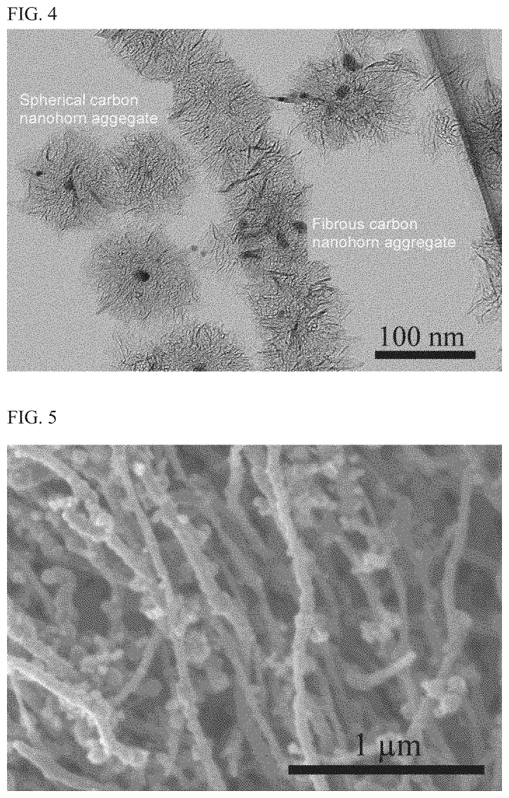

FIG. 4 is a transmission electron microscopic (TEM) image of a fibrous carbon nanohorn aggregate (CNB) and a globular carbon nanohorn (CNHs) fabricated according to an example embodiment of the present invention. FIG. 5 is a scanning electron microscopic (SEM) image. CNB has a structure in which a seed-shaped, a bud-shaped, a dahlia-shaped, a petal dahlia-shaped and/or a petal-shaped (a graphene sheet structure) carbon nanohorn aggregates are one-dimensionally connected. That is, CNB has a structure in which single-walled carbon nanohorns are radially assembled and elongated in a fiber shape. Thus, a fibrous structure contains one or more of these carbon nanohorn aggregates. In addition, carbon nanotubes (CNTs) may be included in the interior of the fibrous carbon nanohorn aggregates. This is due to the formation mechanism of the fibrous carbon nanohorn aggregate according to the present example embodiment as follows.

That is, (1) the catalyst-containing carbon target is rapidly heated by laser irradiation, thereby vaporizing the carbon and catalyst from the target at once and forming a plume by high-density carbon evaporation. (2) At that time, carbon forms carbon droplets of a certain size by collision with each other. (3) In the diffusion process of the carbon droplets, they are cooled gradually to form graphitization of carbon, resulting in the formation of tube-shaped carbon nanohorns. Carbon nanotubes also grow from the catalyst dissolved in the carbon droplets at this time. Then, (4) the radial structure of the carbon nanohorns is connected one-dimensionally with the carbon nanotube as a template, and thereby the fibrous carbon nanohorn aggregates are formed.

The non-transparent particles in FIG. 4 show metals derived from the metal catalyst-containing carbon material used. In the following description, fibrous and globular carbon nanohorn aggregates are combined and referred to simply as carbon nanohorn aggregates.

The diameter of each of the carbon nanohorns (referred to as single-walled carbon nanohorns) including the carbon nanohorn aggregate is approximately 1 nm to 5 nm, and the length is 30 nm to 100 nm. CNB has a diameter of about 30 nm to 200 nm, it is possible to length of about 1 μm to 100 μm. On the other hand, CNHs has approximately uniform size in diameters of about 30 nm to 200 nm.

The CNHs obtained simultaneously is formed in a seed-shaped, a bud-shaped, a dahlia-shaped, a petal dahlia-shaped and/or a petal-shaped one singly or in combination thereof. The seed-shaped one has almost no or no angular projections on its globular surface; the bud-shaped one has slightly angular projections on its globular surface; the dahlia-shaped one is a shape having many angular projections on its globular surface; and the petal-shaped one is a shape having petal-like projections on its globular surface a graphene sheet structure). The petal-dahlia-shaped one has an intermediate structure between the dahlia-shaped one and the petal-shaped one. CNHs is generated in a mixed state with CNBs. Morphology and particle size of the CNHs produced can be adjusted by the type and flow rate of the gases.

Incidentally, CNBs and CNHs can be separated by utilizing a centrifugal separating method or a difference in settling rate after dispersing in solvents. In order to maintain the dispersibility of CNBs, it is preferable to use them as they are without separating from the CNHs. CNB obtained in the present example embodiment is not limited to only the above structure if the single-walled carbon nanohorn is assembled in a fiber shape. Incidentally, the term “fibrous” herein refers to one that can maintain its shape to some extent even by performing the above-described separating operations, and is simply different from one in which a plurality of CNHs are arranged in a series and appear to be fibrous at a glance. Further, in the particle size distribution measurement by the dynamic light scattering measurement, CNB can confirm the peak in the particle size region which clearly differs from the CNHs.

CNBs have high dispersibility compared to other carbon materials having acicular structures, such as carbon fibers and carbon nanotubes. Further, these CNBs and CNHs, since both have a radial structure, there are many contacts at the interface, and they are firmly adsorbed to each other and strongly adsorbed to other material members.

### First Example Embodiment

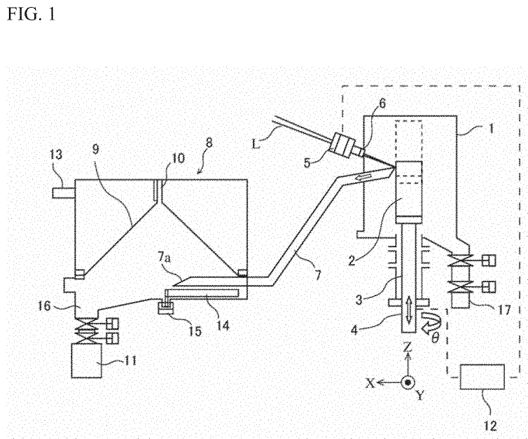

FIG. 1 is a schematic diagram showing a basic configuration of a production apparatus of the CNB according to a first example embodiment of the present invention.

The production apparatus of FIG. 1 is an apparatus for producing carbon nanohorn aggregates including CNB by evaporating carbon with irradiating a laser beam to a cylindrical carbon target containing a metal catalyst selected from a single body of Fe, Ni, Co or a mixture of these two or three in a non-oxidizing gas atmosphere. The apparatus includes a production chamber 1 for generating carbon nanohorn aggregates and a collection chamber 8 coupled to the production chamber 1 through a transfer pipe 7.

The production chamber 1 is provided with a target holding unit (support rod 3) for holding a cylindrical carbon target 2 containing a metal catalyst. Further, in a lower portion of the support rod 3, a drive unit 4 is provided. The drive unit 4 moves the support rod 3, a moving mechanism for moving the cylindrical carbon target 2 in the Z-axis direction (vertical direction in the figure). Further, the drive unit 4 includes a rotation mechanism for rotating the target 2 in the 0 direction with the Z-axis as a rotation axis.

The production chamber 1 also includes a laser irradiation window (e.g., a window made of ZnSe) for irradiating the laser beam L from an un-shown laser oscillator (e.g., a carbon dioxide laser oscillator) to the target 2 in the production chamber 1. The laser irradiation window is provided with a laser focal position adjustment mechanism 5 for focusing the laser beam on a predetermined position.

Further, gas pipelines (not shown) are connected to the production chamber 1. Gas pipelines are for introducing a non-oxidizing gas (nitrogen gas or inert gas such as Ar gas) into the production chamber 1, and are connected to gas canisters (not shown).

Further, a rotary pump 17 for evacuating the interior of the production chamber 1 is attached to the chamber 1 via a valve.

On the other hand, the collection chamber 8 includes a filter hanging jig 10 for hanging a filter (e.g., bag filter) 9 in the center of an upper wall portion thereof. The collection chamber 8 includes a cylindrical peripheral wall portion 8a. The filter 9 is formed in a conical shape, the lower edge thereof is suspended so as to contact the inner peripheral wall of the collection chamber 8.

In addition, the collection chamber 8 includes a collection port 51 for collecting the generated carbon nanohorn aggregates, a scraping plate 14 for scraping the carbon nanohorn aggregates deposited on the bottom wall and for dropping them into the collection port 51, and a motor 53 for rotating and driving the scraping plate 14. The motor 15 has a drive shaft parallel to the Z-axis (vertical direction in the figure) in the center of the bottom wall portion of the collection chamber 8, and rotationally drives the scraping plate 14 being in contact with the bottom wall portion of the collection chamber 8. Further, the collection port 16, the collection container 11 is attached via a valve.

Further, the collection chamber 8 has an exhaust port 13 provided in an upper portion of the peripheral wall portion 8a. The exhaust port 13 is connected to an exhaust mechanism (e.g., a dry pump) for evacuating the inside of the collection chamber 8.

The transfer pipe 7 making the connection between the production chamber 1 and the collection chamber 8 is for transferring the carbon nanohorn products generated in the production chamber 1 to the collection chamber 8. For this purpose, an end of the transfer pipe 7 in the production chamber is provided around a laser irradiation portion of the target 2. In other words, the laser irradiation to the target 2 is performed near the end of the transfer pipe 7 on the production chamber side. On the other hand, another end (outlet) 7a of the transfer pipe 7 in the collection chamber is provided in the lower portion (near the bottom wall portion) of the collection chamber 8, eccentrically from the chamber centerline (so that the outlet faces tangential direction) and so as not to hinder the movement of the scraping plate 14.

Next, the operation of the production apparatus of FIG. 1 will be described.

In the production chamber 1, when the target 2 is irradiated with a laser beam in a non-oxidizing gas atmosphere to evaporate carbon, a product (plume) including carbon nanohorn aggregates is produced. At this time, while introducing an atmospheric gas into the production chamber 1, if the inside of the collection chamber 8 is exhausted (if the pressure of the collection chamber 8 lower than the pressure in the production chamber 1), it is possible to make a flow of the atmospheric gas through the transfer pipe 7. Since the end of the transfer pipe 7 in the production chamber 1 is provided around the laser irradiation portion of the target 2 as described above, products including carbon nanohorn aggregates produced in the production chamber 1 are transferred to the collection chamber 8 by a flow of ambient gas.

Further, the outlet 7a of the transfer pipe 7 at the collection chamber side is eccentrically provided in the lower portion of the collection chamber 8, whereas the exhaust port 13 is provided in the upper portion. The atmospheric gas flowing into the collection chamber 8 via the transfer pipe 7 moves upward while traveling along the inner peripheral wall of the collection chamber 8. That is, the atmospheric gas flowing into the collection chamber 8 helically flows from the bottom to top. The atmospheric gas having reached the upper portion of the collection chamber 8 is exhausted from the exhaust port 13 to the outside through the filter 9.

Among the carbon nanohorn aggregates transferred to the collection chamber 8 by the atmospheric gas, the product component reaching to the upper portion of the collection chamber 8 with the flow of the atmospheric gas is trapped in the filter 9. The other product components not having been able to reach the upper portion of the collection chamber 8 without riding the flow of the atmospheric gas are deposited on the bottom wall of the collection chamber 8 or adhere to the inner peripheral wall thereof.

Powders transferred to the collection chamber 8 through the transfer pipe 7 includes carbon nanohorn aggregates (fibrous and globular), graphite components and amorphous components. Among them, most of the other production components (graphite components and amorphous components), each of which is relatively unlikely to be aggregated and has a low mass, are trapped by reaching the filter 9 to the flow of the atmospheric gas upward in the collection chamber 8. On the other hand, the carbon nanohorn aggregates tends to be cohesion, the cohered powder cannot reach the filter 9 because the mass increases, drops to the bottom wall portion of the collection chamber 8 and deposits.

In the present example embodiment, the gas flow helically moves up along the inner peripheral wall of the collection chamber 8. In this case, when compared with the case where the gas flow moves up linearly, it is possible to promote the cohering of the carbon nanohorn aggregate. As a result, the purity of the carbon nanohorn aggregate of the product dropped on the bottom wall of the collection chamber 8 can be further enhanced.

Next, when the motor 15 is driven to rotate the scraping plate 14, the product components deposited on the bottom wall of the collection chamber 8 are scraped and collected in the collection port 16. The product component collected in the collection port 16 is collected into the sample collection container 11 through the valve.

In the sample collection container 11, an inert liquid to the carbon nanohorn aggregates may be filled and the collected carbon nanohorn aggregates can be collected by immersing in the liquid. The inert liquids include water and organic solvents with a higher boiling point than water.

As described above, in the production apparatus according to the present example embodiment, by a simple mechanism using a gas flow using the transfer pipe 7 and the collection chamber 8 as a separation means, it is possible to separate a product component containing many impurities and another product component containing many carbon nanohorn aggregates. Thus, it is possible to easily obtain a high purity carbon nanohorn aggregate.

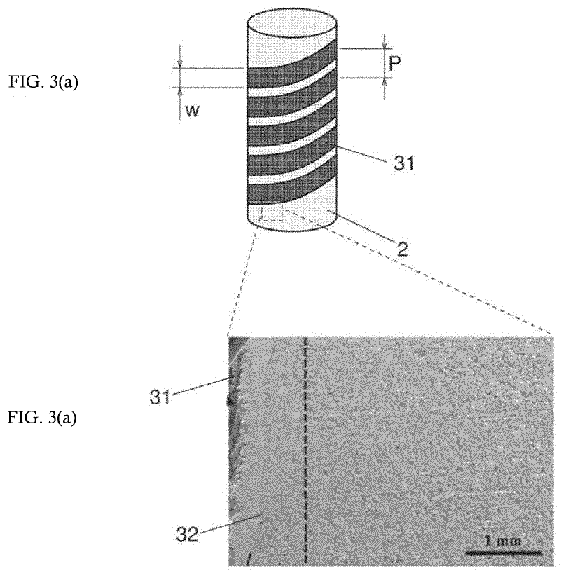

Thus, in the method of evaporating by irradiating a laser beam to the carbon target by laser ablation, the peripheral portion where the laser beam is irradiated is also thermally affected, such as the changes of the crystalline state of the carbonaceous and the distribution of the catalyst metal (referred to as an altered region). FIG. 3 shows an example of the altered region 32 of the target 2 after laser irradiation. Up to the dotted line portion of the scanning electron microscope image of FIG. 3(b), it seems that there is an influence on the target after irradiation, and therefore, such a region is referred to as the altered region in the present invention. In the production of nano-carbons including carbon nanohorns by conventional laser ablation, it has been known that a method is performed while moving the irradiation position so that the target surface is even during laser irradiation from the viewpoint of maintaining uniform laser irradiation. In terms of suppressing the material cost, it is preferable to use up all of the catalyst-containing carbon target. The inventor had found that CNB does not normally produce if the laser beam is irradiated to the altered region as described above. As a result, laser energy is wasted.

Here, in order to use the target efficiently from an industrial viewpoint, it is conceivable a method of passing the laser beam once close to the region where the laser beam has passed, it is necessary to pass the laser avoiding the altered region. Therefore, in the present example embodiment, in conjunction with the laser power and the laser spot diameter by the laser focus position adjusting mechanism 5, a control unit 12 for controlling the rotation and movement of the target 2 by the driving unit 4 is provided. In the control unit 12, the rotational speed in the drive unit 4 so that the laser is irradiated avoiding the altered region on the target, to control the vertical movement speed.

Accordingly, a first example embodiment of the present invention relates to an apparatus for producing carbon nanohorn aggregates including fibrous carbon nanohorn aggregates, the apparatus includes: a target holding unit holding a cylindrical carbon target containing a metal catalyst selected from a single body of Fe, Ni, Co or a mixture of these two or three, a light source irradiating a laser beam on the surface of the carbon target, a production chamber configured to irradiate the carbon target with the laser beam in an atmosphere of non-oxidizing gas to produce a product including a fibrous carbon nanohorn aggregate, a collection mechanism collecting the product, a rotation mechanism rotating the carbon target, and a moving mechanism moving the carbon target in the axial direction, wherein the apparatus further includes a control unit being provided for controlling the rotation mechanism and the moving mechanism so that the power density of the laser beam irradiated to the surface of the carbon target is substantially constant, and the irradiation position of the laser beam is moved to a region adjacent to a region previously irradiated by the laser beam, an interval being formed therebetween that is equal to or larger than the width of an altered region formed on the periphery of the region irradiated by the laser beam. The altered region tends to be wider as the laser energy density is greater, the moving speed of the laser irradiation position is slower, and the thermal conductivity of the target is higher.

Here, “to move the laser irradiation position so that the power density of the laser beam is substantially constant”, by the irradiation position of the laser beam (spot) is gradually moved at a constant speed, a substantially constant power density.

At this time, if the moving speed of the laser spot is too slow, the raw material from the target cannot be evaporated and precipitates as a deposit on the target. The precipitates are mainly graphite and carbon nanotubes, and some CNHs is formed, but CNB is not formed. Although the detail is not clear, the slightly evaporated raw material is consumed in the production of CNHs, and it is considered that CNBs are no longer formed. Also, even if the moving speed becomes too fast, it becomes mainly CNHs and no CNB is generated. Therefore, the moving speed is set to be appropriately optimized according to the laser power, the spot diameter of the laser, and the catalyst amount of the catalyst-containing carbon target. For example, as shown in the Examples described below, when using a carbon target containing lat. % iron, the generation of CNB has been confirmed in a range of about 5 cm/min to about 35 cm/min at a laser power of 3.2 kW and a spot diameter of 1.5 mm (power density of 181 kW/cm²). In the present invention, the carbon target to be used, the laser power, depending on the spot diameter, the moving speed is preferably 3 cm/min or more, 50 cm/min or less.

For laser ablation, CO₂ laser, excimer laser, YAG laser, semiconductor laser, etc., can be appropriately used as long as the target can be heated to a high temperature. CO₂ laser whose output can be easily increased is most suitable. The output of the CO₂ laser can be appropriately utilized, but preferably an output of 1.0 kW to 10 kW, and more preferably an output of 2.0 kW to 5.0 kW. If it is smaller than this range, since almost the target does not evaporate, undesirable from the viewpoint of the amount produced. If it is greater than this range, it is undesirable because the impurities such as graphite and amorphous carbon increases. In addition, the laser can be performed with continuous irradiation and pulse irradiation. For mass production, continuous irradiation is preferred.

The spot diameter of the laser beam can be selected from a range in which the irradiated area is about 0.02 cm² to 2 cm², that is, a range of 0.5 mm to 5 mm. Here, the irradiation area can be controlled by the laser output and the degree of condensation at the lens.

Further, when the laser beam is irradiated to the target, the target is heated, the plume (light emission) is generated and evaporated from the surface of the target. At that time, when the laser beam forming a 45° angle with the surface of the cylindrical target is irradiated, the plume occurs in a direction perpendicular to the surface of the target. Therefore, the irradiation position should be within the range where the laser beam does not hit the plume and does not pass through any part other than the target. With respect to the cylindrical target, arranged slightly shifted irradiation position in the opposite direction of the rotation direction than the position to be substantially perpendicular toward the rotation center axis. Preferably the angle formed between the tangent of the target surface at the laser spot center is a position where 30° or more. In this case, although the shape of the laser spot becomes substantially oval each time in the traveling direction side rather than a perfect circle, the spot diameter is defined as the diameter of the direction perpendicular to the traveling direction at the spot center.

When the laser beam is irradiated continuously by simply rotating in this way, it will be irradiated again to the already irradiated area after one rotation, in order not to irradiate the already irradiated area, at the same time as rotating the cylindrical target, it is moved in the rotation axis direction to irradiate the laser beam so as to be a helical trajectory. At this time, the traveling speed of the irradiation position becomes faster by the amount of movement in the rotation axis direction. In the region adjacent to the region where the laser beam was previously irradiated in a direction different from the traveling direction, for irradiating and moving at a distance of more than the width of the altered region, to control the helical trajectory to a pitch of more than ‘the diameter of the laser spot+the width of the altered region’. Here, the “pitch” refers to the distance between the centers of the laser spots, therefore, the moving speed in the rotation axis direction (referred to as the feeding speed) needs to be a speed that satisfies this pitch. Thus, adjusting the rotation speed, feeding speed.

Pressure in the production chamber can be used at 13,332.2 hPa (10,000 Torr) or less, but the closer the pressure is to the vacuum, the more easily carbon nanotubes are formed and carbon nanohorn aggregates are not obtained. Preferably at 666.61 hPa (500 Torr) to 1,266.56 hPa (950 Torr), more preferably used in the vicinity of normal pressure (1,013 hPa (1 atm 760 Torr)) is also suitable for mass synthesis and cost reduction.

The production chamber can be set to any temperature, preferably 0 to 100° C., more preferably used at room temperature is also suitable for mass synthesis and cost reduction.

In the production chamber, the above atmosphere is made by introducing nitrogen gas and a noble gas alone or mixed. These gases can flow from the production chamber to the collection chamber and the material produced can be recovered by this gas flow. It may also be a closed atmosphere by the gas introduced. A flow rate of the atmospheric gas can be used any amount, preferably the flow rate in the range of 0.5 L/min to 100 L/min is appropriate. In the process of evaporation of the target, the gas flow rate is controlled to be constant. To constant gas flow rate can be performed by matching the supply gas flow rate and the exhaust gas flow rate. When performed near atmospheric pressure, it can be performed by exhausting by extruding the gas in the production chamber with the supply gas.

In the case of a cylindrical carbon target having a diameter of 3 cm, the rotational speed is preferably 0.8 to 3.0 rpm, 0.8 to 1.8 rpm is particularly preferred. Further, the spot diameter, i.e. when the width W of the irradiation area 31 of FIG. 3(a) is 1.5 mm, the feeding speed is preferably 1 to 50 mm/min, more preferably 2 to 30 mm/min. In this range, enough vapor is obtained to promote the formation of CNB, and laser irradiation can be performed with the helical adjacent irradiated area avoiding the altered area. Further, by the laser beam is always irradiated at a constant speed on the target surface of the unirradiated, the power density of the laser beam irradiated on the surface of the target is substantially constant. For example, laser power 3.2 kW to a carbon target having a diameter of 3 cm containing 1 at. % iron, a spot diameter of 1.5 mm, when irradiated with laser beam under the conditions of 1 rpm, as shown in FIG. 3(b), the altered region 32 of about 1 mm width is confirmed. Therefore, the pitch P of the helical irradiation area 31 is preferably 2.5 mm or more, in this case, the feeding speed is preferably 2.5 mm/min or more.

Depending on the amount of catalyst contained in the carbon target, the amount of formation of CNB changes. Although appropriately selected with respect to the amount of catalyst, the amount of catalyst is preferably 0.3 to 20 atomic % (at. %), more preferably 0.5 to 3 at. %. When the amount of catalyst is less than 0.3 at. %, the fibrous carbon nanohorn aggregate becomes very small. Further, when it exceeds 20 at. %, it is not appropriate because the cost increases because the amount of catalyst increases. Catalyst, Fe, Ni, Co alone, or can be used by mixing. Among them it is preferable to use Fe (iron) alone, it is particularly preferable in terms of the amount of production of CNB to use a carbon target containing 1 at. % or more 3 at. % or less of iron.

As described above, the formation of CNB is affected by physical properties (thermal conductivity, density, hardness, etc.) of the carbon target containing a catalyst and the content of the catalyst. The catalyst-containing carbon target having low thermal conductivity and low density, and being soft is preferred. That is, the second example embodiment of the present invention is characterized by using a catalyst-containing carbon target having 1.6 g/cm³ or less of the bulk density and 15 W/(m·K) or less of the thermal conductivity. By making bulk density and thermal conductivity in these ranges, it is possible to increase the formation rate of CNB. When bulk density and thermal conductivity exceed these values, the formation rate of CNHs and other carbon structures increases, and the formation of CNBs may be almost eliminated. By using such a target, the energy given from the laser causes the target to evaporate instantaneously to form a dense space in which carbon and catalyst form, and the carbon released from the target is gradually cooled under atmospheric pressure environment to produce CNB.

Bulk density and thermal conductivity can be set a desired value by adjusting the molding pressure and the molding temperature when producing the amount and target of the catalyst metal.

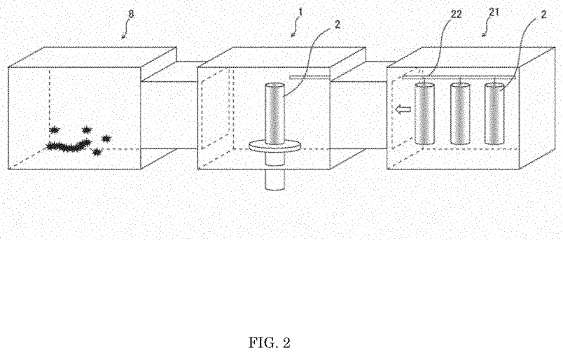

FIG. 2 is a diagram illustrating a schematic of an apparatus serving as another embodiment of the present invention, wherein the production chamber 1 and the collection chamber 8 have the same configuration as FIG. 1. Furthermore, in the apparatus shown in FIG. 2, a storage container (target reservoir 21) for storing the unused cylindrical carbon target, has a function of automatically replacing the target 2 irradiated one way in the production chamber 1 to a new target 2 in the target reservoir 21. Here, the target 2 is suspended to the rail 22 as an exchange mechanism, from the target reservoir 21 is conveyed to the production chamber 1. The spent target is discharged from the production chamber 1 by a recovery mechanism (not shown).

Above, it shows an example of using the target 2 upright in the vertical direction (Z direction), the apparatus of the present invention is not limited thereto, the horizontal direction (e.g., Y direction) to place the target, it is also possible to rotate while moving in the horizontal direction.

### EXAMPLES

Hereinafter, the present invention will be described in more detail by way of Examples. Of course, the present invention is not limited to the following Examples.

### Experimental Example 1

A cylindrical carbon target containing 1 at. % of iron (diameter: 3 cm, bulk density of about 1.4 g/cm³, thermal conductivity of about 5 W/(m·K)) was installed in the target holder in the production chamber. The inside of the chamber was made to be a nitrogen atmosphere. While rotating the carbon target at a rate of 0.5 rpm (Level 1), 1 rpm (Level 2), 2 rpm (Level 3) and 4 rpm (Level 4), CO₂ gas laser beam was continuously irradiated to the target for 1 rotation or less time (30 seconds at 0.5-2 rpm, 15 seconds at 4 rpm). The laser power was adjusted to be 3.2 kW, the spot diameter to be 1.5 mm, and the irradiation angle to be about 45 degrees at the spot center. The flow rate of nitrogen gas was controlled to be 10 L/min, 700-950 Torr. The temperature in the reaction vessel was room temperature.

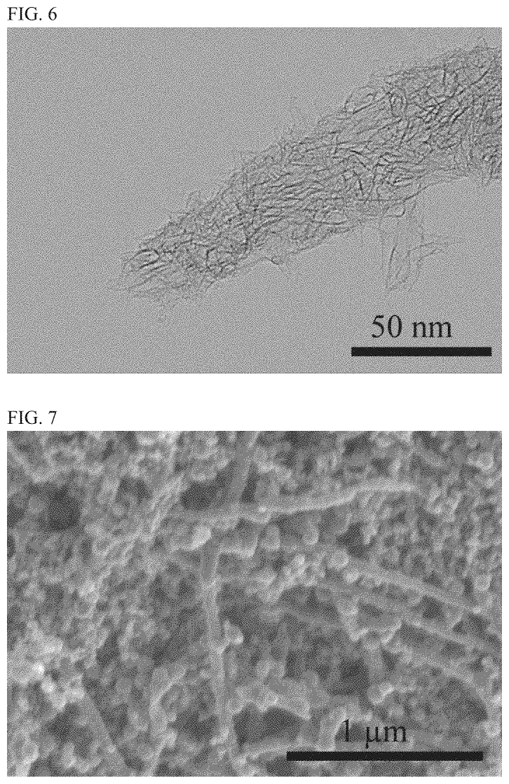

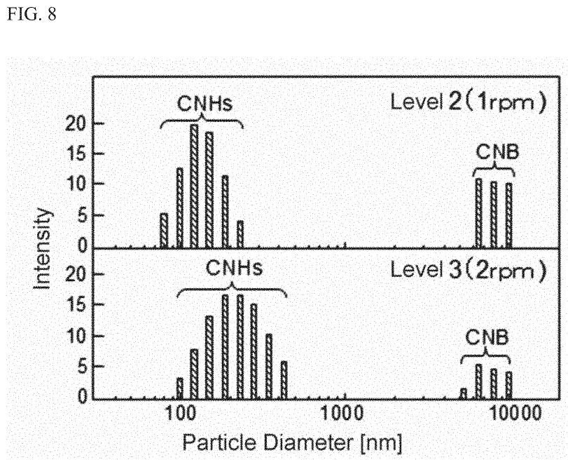

FIG. 5 is an SEM image of a sample of Level 2. CNB and CNHs are observed. It was found that very many CNBs were produced. FIG. 6 is a TEM photograph, and it was found that the CNB had a single-walled carbon nanohorn with a diameter of 1-5 nm and a length of about 40-50 nm assembled in a fibrous form. The CNB itself has a diameter of about 30-100 nm and a length of several μm to several tens of μm. The CNHs were mostly of almost uniform sizes with diameters ranging from about 30 to 200 nm. FIG. 7 is an SEM image of a sample of Level 3. In comparison with 1 rpm, it was proven that the generation quantity of CNB was lowered and the generation quantity of CNHs was large. FIG. 8 is a particle size distribution obtained by dynamic light scattering measurements of Level 2 and Level 3 samples. The range of 100-500 nm is the CNHs and the range of 5-15 μm is the CNB. Level 2 contains more CNBs than Level 3. In addition, in the sample of Level 1, almost no CNB was obtained, and CNHs, graphite, carbon nanotube were produced. This is because the moving speed of the irradiation position was slow and many graphite and carbon nanotubes were deposited on the target. On the other hand, in the sample of Level 4, almost no CNB was obtained, and CNHs and amorphous carbon were obtained. Thus, it was confirmed that the generation rate of CNB was changed by optimizing the moving speed of the irradiation position.

### Experimental Example 2

An experiment was performed in which the target was rotated in a helical in a time period of one rotation or more by controlling the target feeding speed to 1.5 mm/mim (Level 5) and 5 mm/mim (Level 6) with the rotation speed of the target at 1 rpm. Other conditions are the same as in Example 1.

Samples prepared in Level 5 and Level 6 were compared. As a result of observing the sample of Level 5 by SEM, carbon fiber and graphite were produced. On the other hand, CNBs and CNHs were generated in Level 6. Observing the surface of the target, the target color was discolored near the laser irradiation so as to change the state of the target. Therefore, it was found that the feed of the target should be larger than the irradiation diameter of the laser and irradiated avoiding from the altered region.

### Comparative Experimental Example 1

A carbon target containing 1 at. % of iron (bulk density of about 1.7 g/cm³, thermal conductivity of about 16 W/(m·K)) were used. Other conditions are the same as Level 2 in Experimental Example 1.

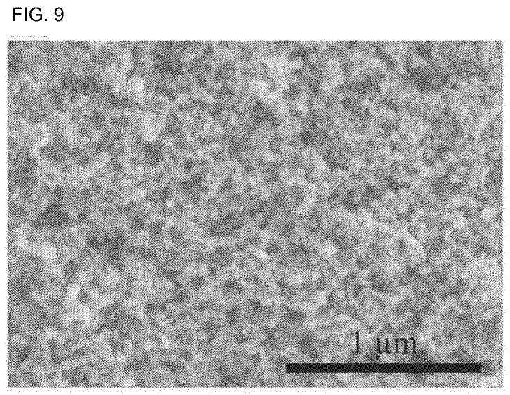

FIG. 9 is a SEM image of a sample prepared in Comparative Experimental Example 1. No CNB was produced, and CNHs and amorphous carbon and graphite fibers were produced. Therefore, as used in Experimental Examples 1 and 2, the catalyst-containing carbon target was found to produce CNB when the thermal conductivity is low and the density is low.

### DESCRIPTION OF SYMBOLS

1 Production chamber
2 Cylindrical catalyst-containing carbon target
3 Support rod
4 Drive unit
5 Laser focal position adjustment mechanism
6 Irradiation window
7 Transfer pipe
8 Collection chamber
9 Filter
10 Filter hanging jig
11 Sample collection container
12 Control unit
13 Exhaust port
14 Scraping plate
15 Motor
16 Collection port
17 Rotary pump
21 Target reservoir
22 Replacement mechanism (rail)
31 Irradiated area
32 Altered region

1. A production apparatus for manufacturing carbon nanohorn aggregates including fibrous carbon nanohorn aggregates, the apparatus comprising:
a target holding unit holding a cylindrical carbon target containing a metal catalyst selected from a single body of Fe, Ni, Co or a mixture of these two or three,
a light source irradiating a laser beam on the surface of the carbon target,
a production chamber configured to irradiate the carbon target with the laser beam in an atmosphere of non-oxidizing gas to produce a product including a fibrous carbon nanohorn aggregate,
a collection mechanism collecting the product,
a rotation mechanism rotating the carbon target, and
a moving mechanism moving the carbon target in the axial direction,
wherein the apparatus further comprises a control unit being provided for controlling the rotation mechanism and the moving mechanism so that the power density of the laser beam irradiated on the surface of the carbon target is substantially constant, and the irradiation position of the laser beam is moved to a region adjacent to a region previously irradiated by the laser beam, an interval being formed therebetween that is equal to or larger than the width of an altered region formed on the periphery of the region irradiated by the laser beam.

2. The production apparatus according to claim 1, wherein the moving speed of the irradiated position of the laser beam is in a range of 3 cm/min to 50 cm/min.

3. The production apparatus according to claim 2, wherein the power of the laser beam is in a range of 2.0 kW to 10 kW.

4. The production apparatus according to claim 2, wherein the rotation of the target and the movement of the irradiation position are performed so as to move helically the irradiation position of the laser beam on the surface of the cylindrical carbon target.

5. The production apparatus according to claim 4, wherein a pitch of the helically moving the irradiation position of the laser beam is controlled so as to be equal to or greater than a value obtained by adding a width of the altered region to an irradiation spot diameter of the laser beam.

6. The production apparatus according to claim 1, wherein moving mechanism is a mechanism for moving the cylindrical carbon target vertically in the state of fixing the irradiation direction of the laser beam.

7. The production apparatus according to claim 1, further comprising:
a storage container coupled to the production chamber for storing unused cylindrical carbon targets; and
an exchange mechanism for replacing an unused cylindrical carbon target in the storage container to one of the cylindrical carbon targets in the production chamber upon completion of irradiation.

8. The production apparatus according to claim 1, wherein the collection mechanism comprises:
a collection chamber coupled to the production chamber such that the product is introduced by using gas;
a trapping unit provided at an upper portion of the collection chamber; and
a collection unit provided at a lower portion of the collection chamber,
wherein
the collection chamber is coupled to the production chamber such that the gas spirally moves up in the collection chamber,
the trapping unit traps produced components other than the carbon nanohorn aggregate by moving up with the gas in the collection chamber, and
the collection unit collects the carbon nanohorn aggregates, which aggregate by spirally moving up the gas in the collecting chamber, and then fall down.

9. The production apparatus of claim 8, wherein the collection unit comprises a collection container containing a liquid inert to the carbon nanohorn aggregate, and the collection container collects the generated carbon nanohorn aggregate by being suspended in the liquid.

10. The production apparatus according to claim 1, wherein the catalyst is Fe.
